(19) United States
(12) Patent Application Publication
(10) Pub. No.: US 2016/0065049 A1
(43) Pub. Date: Mar. 3, 2016

(54) LCL CAPACITOR CURRENT COMPENSATION AND CONTROL METHOD BASED ON DIVISION AND SUMMATION TECHNIQUE

(71) Applicant: National Tsing Hua University, Hsin-Chu City (TW)

(72) Inventors: TSAI-FU WU, Hsin-chu City (TW); LI-CHUN LIN, Hsin-Chu City (TW); NING YAO, Hsin-Chu City (TW)

(21) Appl. No.: 14/540,039

(22) Filed: Nov. 13, 2014

(30) Foreign Application Priority Data
Aug. 26, 2014 (TW) 103129298

(51) Int. Cl. H02M 1/12; G01R 31/40

(52) U.S. Cl. CPC H02M 1/12; G01R 31/40

(57) ABSTRACT

An LCL capacitor current compensation and control method based on division and summation technique, comprising following steps: calculating new reference current i*ₗᵣ=power grid reference current (I_{gr})+estimated capacitor current ( [symbol] ); calculating duty cycle ratio d of respective switches in inverter to obtain inductor current (iₗ), through using corresponding division-and-summation digital control characteristic equation (A), (B), (C), or (D), as based on inverter code of various inverter types; calculating power grid current (i_{g})=inductor current (iₗ)−capacitor current (i_{c}); calculating voltage across inductor at power grid side (v_{c}−vₚ)=impedance (Z_{g}) of said inductor at power grid side x power grid current (i_{g}); utilizing equation (4) to calculate voltage across capacitor (v_{c}); estimating capacitor current ( [symbol] )=voltage across said capacitor (v_{c})/filtering capacitor impedance (Z_{c}); and utilizing equation (3) to estimate capacitor current ( [symbol] ).

### BACKGROUND OF THE INVENTION

### Field of the Invention

The present invention relates to an LCL capacitor current compensation and control method, and in particular to an LCL capacitor current compensation and control method based on division and summation technique.

### THE PRIOR ARTS

With the advent of the Industrial Revolution since the 18^{th} century, the petrochemical fuel, such as coal, petroleum, and natural gas are utilized and consumed in huge quantities. However, due to the exploitation for more than two hundred years, the energy resources are near depletion, and the energy crisis is getting serious. According to a survey conducted recently, with the petroleum resources presently available, it can only sustain industrial development and consumption for several decades before it comes to a complete depletion. In addition, for the uranium used for nuclear power generation, that will also be used up in the coming decades. Therefore, the green energy power generation is considered as an ideal and alternative energy resource, and thus it has caught much of the attention as the hope of energy development for the future.

In general, the electricity produced by green energy power generation (such as solar energy power generation, wind energy power generation . . . ) can be handled in two approaches: stored in a battery, or merged directly into a power grid of a power company. Wherein, the shortcoming of utilizing batteries is that, its power storage capacity and service life are limited, and its cost is high. Moreover, in case the power produced by green energy resources is merged directly into a power grid of a power company (such as Taiwan Power Company) through an inverter, the power loss during battery charging and discharging can be eliminated, to raise efficiency of power generation.

In merging the power produced by green energy resources into a power grid, the merged grid current of the inverter must conform to certain Specification, such as IEEE 1547.2-2008 and 519-1992. Therefore, there are stringent demands and restrictions on the harmonics of such a merged grid current In general, the harmonic distortion must be reduced to 3˜5% . In order to fulfill the requirement of this specification, an Inductor-Capacitor-Inductor (LCL) filter has to be added between the inverter and the power grid.

In this respect, refer to FIG. 1 for a circuit and control block diagram for a conventional LCL inverter (that is also the circuit and control block diagram for a single-phase double-wire bi-directional inverter system utilized in implementing the method of a first embodiment of the present invention as explained as follows). As shown in FIG. 1, the conventional LCL inverter has the inherent problem of instability, that could cause harmonic distortion in the merged grid current, as such leading to the degradation of the sensitivity and accuracy of the electronic device receiving and using this kind of merged grid current. In order to stabilize the merged grid power system, various designs and methods are proposed by people of this field, to improve or suppress the harmonics in the merged grid current.

In the documents of the prior art, a SPWM or SVPWM modulation approach is proposed, to perform analysis and control by considering the inverter a voltage source, such as Adaptive Current Control, PR Control, and Current Feedback Control. Though this type of control and strategy is capable of effectively improving the harmonic problem of the merged grid current, yet it has not dealt with the stability of LCL inverter output impedance and power grid impedance in a merged power grid. In another prior art, a stability criteria is proposed for inverter vs impedance. In a further prior art, an impedance shaping method is proposed to further deal with the problem of impedance stability, to raise the stability of merging an inverter into a power grid. Though this method proves to be feasible, yet the phase angle of its output impedance is very close to −90 degrees at low frequency, and this could lead to system oscillation, when the grid impedance is high. In addition, in the design of a controller, it fails to take into consideration that the inductance of the inverter can be varied with current, and this could lead to system instability in high power application.

Therefore, presently, the design and performance of merged power grid using LCL inverter is not quite satisfactory, and it has much room for improvement.

### SUMMARY OF THE INVENTION

In view of the problems and drawbacks of the prior art, the present invention provides an LCL capacitor current compensation and control method based on division and summation technique, to suppress or eliminate the harmonics in currents of a merged power grid.

In general, the ideal and standard value of power voltage provided by a Power Company, such as Taiwan Power Company is 220V of 60 Hz, with zero harmonics. Any deviation from this value is considered as power grid instability. In practice, the voltage of power provided by Taiwan Power Company is 220V+10%, having voltage frequency 60 Hz+1%, with 3% to 5% harmonics.

The source of harmonics could come from the power generation equipment during power generation, or it could also come from the device using the power in the power grid. In a power grid, both voltage and current could produce harmonics. Wherein, the voltage harmonics can be handled by using a voltage stabilization technique; while the present invention mainly deals with harmonics in a current, and in particular, it aims at suppressing or eliminating harmonics in a current of a merged power grid to avoid distortion, in achieving ideal sine waves.

In order to overcome the shortcomings and drawbacks of the prior art, the present invention provides an LCL capacitor current compensation and control method based on division and summation technique (FCCC). The compensation and control method takes into considerations of inductance variations, and it views an inverter as a current source. As such, through modifying reference current of inverter to compensate for the capacitor current for a distorted voltage, to suppress harmonics in current of a merged power grid, so as to achieve ideal sine wave of the current. The method of the present invention has the characteristics of accurately tracing power grid current, achieving high voltage harmonic suppression ratio, and realizing high stability tolerance.

In order to achieve the objective mentioned above, the present invention provides an LCL capacitor current compensation and control method based on division and summation technique, including the following steps: calculating the new reference current i*ₗᵣ=power grid reference current (I_{gr})+estimated capacitor current ( [symbol] ) (step 1); calculating the duty cycle ratio d of the respective switches in the inverter to obtain the inductor current (iₗ), through using the corresponding division-and-summation digital control characteristic equation (A), (B), (C), or (D), as based on the inverter code of various inverter types (step 2); calculating the power grid current (i_{g})=inductor current (iₗ)−capacitor current (i_{c}) (step 3); calculating voltage across inductor at power grid side (v_{c}−vₚ)=impedance (Z_{g}) of inductor at power grid side x power grid current (i_{g}) (step 4); utilizing equation (4) to calculate voltage across capacitor ( [symbol] ) (step 5); estimating capacitor current ( [symbol] )=voltage across capacitor (v_{c})/filtering capacitor impedance (Z_{c}) (step 6); and utilizing equation (3) to estimate capacitor current ( [symbol] ) (step 7).

In the present invention, the types of inverter utilized in implementing the LCL capacitor current compensation and control method based on division and summation technique may include the following: single-phase double-wire bi-directional inverter (FIG. 1), with its inverter code set as A01; three-phase four-wire bi-directional inverter (FIG. 7), with its inverter code set as A02;

three-phase three-wire bi-directional inverter (FIG. 8), with its inverter code set as A03; and single-phase three-wire bi-directional inverter (FIG. 9), with its inverter code set as A04.

In step 2 mentioned above, in case the inverter code is A01, then execute the division-and-summation digital control characteristic equation (A); in case the inverter code is A02, then execute the division-and-summation digital control characteristic equation (B); in case the inverter code is A03, then execute the division-and-summation digital control characteristic equation (C); and in case the inverter code is A04, then execute the division-and-summation digital control characteristic equation (D), in achieving the objective of suppressing harmonics in a merged grid current.

The advantages of the present invention are that, the compensation and control method takes into considerations of inductance variations, and it views an inverter as a current source. As such, through modifying reference current of inverter to compensate for the capacitor current for a distorted voltage, it is able to suppress harmonics in current of a merged power grid, so as to achieve ideal sine wave of the current. The method of the present invention is characterized in that, it is capable of accurately tracing power grid current, achieving high voltage harmonic suppression ratio, and realizing high stability tolerance. As such, it could avoid the drawbacks and shortcomings of the prior art that, the harmonics in a power grid current leading to degradation of sensitivity and accuracy for the various electronic devices receiving and using the current in the merged power grid.

Further scope of the applicability of the present invention will become apparent from the detailed descriptions given hereinafter. However, it should be understood that the detailed descriptions and specific examples, while indicating preferred embodiments of the present invention, are given by way of illustration only, since various changes and modifications within the spirit and scope of the present invention will become apparent to those skilled in the art from this detailed descriptions.

### BRIEF DESCRIPTION OF THE DRAWINGS

The related drawings in connection with the detailed descriptions of the present invention to be made later are described briefly as follows, in which:

FIG. 1 is a circuit and control block diagram for a single-phase double-wire bi-directional inverter system according to a first embodiment of the present invention;

FIG. 2 is an S domain control block diagram of an equivalent circuit of a single-phase double-wire bi-directional inverter system utilized in implementing the first embodiment of the present invention;

FIG. 3 is a flowchart of the steps of an LCL capacitor current compensation and control method based on division and summation technique, according to a first embodiment of the present invention;

FIG. 4 is a plot of output impedance (Z₀) vs power grid impedance (Z₁) for an LCL capacitor current compensation and control method based on division and summation technique according to a first embodiment of the present invention;

FIG. 5 is a plot of output impedance (Z₀) vs power grid impedance (Z₁) taking into consideration of variations of inductors Ls and Lg, as based on the SPWM modulation approach according to the prior art;

FIG. 6(a) is real test curves for a merged local power grid mode (iₗ and i_{g}: 10 A/div; vₚ and v_{dc}: 100 v/div; time: 10 ms/div) under the test conditions of power grid distortion (Zₗ=2 mH), without adopting the capacitor current compensation and control of the present invention;

FIG. 6(b) is real test curves for a merged local power grid mode (iₗ and i_{g}: 10 A/div; vₚ and v_{dc}: 100 v/div; time: 10 ms/div) under the test conditions of power grid distortion (Zₗ=2 mH), while adopting the capacitor current compensation and control of the present invention;

FIG. 7 is a circuit and control block diagram for a three-phase four-wire bi-directional inverter system according to a second embodiment of the present invention;

FIG. 8 is a circuit and control block diagram for a three-phase three-wire bi-directional inverter system according to a third embodiment of the present invention; and

FIG. 9 is a circuit and control block diagram for a single-phase three-wire bi-directional inverter system according to a fourth embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

It has to be noted that, in the present invention, numerous equations are utilized to explain the contents of the present invention, and two of them are quite voluminous as to each occupies a whole page. For this reason, all of those equations are listed at the end of the Specification to facilitate the reader to conduct continuous reading without being distracted by the equations.

In the descriptions of embodiments 1 to 4, the following systems are used: single-phase double-wire bi-directional inverter system, three-phase four-wire bi-directional inverter system, three-phase three-wire bi-directional inverter system, and single-phase three-wire bi-directional inverter system, and that all belong to the prior art. In using the systems mentioned above to merge the self-generated electric power into a local power grid, the current of the merged power grid tends to produce harmonics, and it is thus seriously distorted. However, when utilizing the systems mentioned above to implement the LCL capacitor current compensation and control method based on division and summation technique of the present invention, the harmonics in the current of the merged power grid can be suppressed or eliminated, to produce ideal sine waves of current. As such, it can avoid the drawbacks and shortcomings of the prior art in that, in the prior art, the electronic devices receiving and using such merged power grid current will be adversely affected by the harmonics, such that its sensitivity and accuracy tend to degrade. Through using the compensation and control method of the present invention, the drawbacks and shortcomings of the prior art can be avoided.

### First Embodiment

### Single-Phase Double-Wire Bi-Directional Inverter System

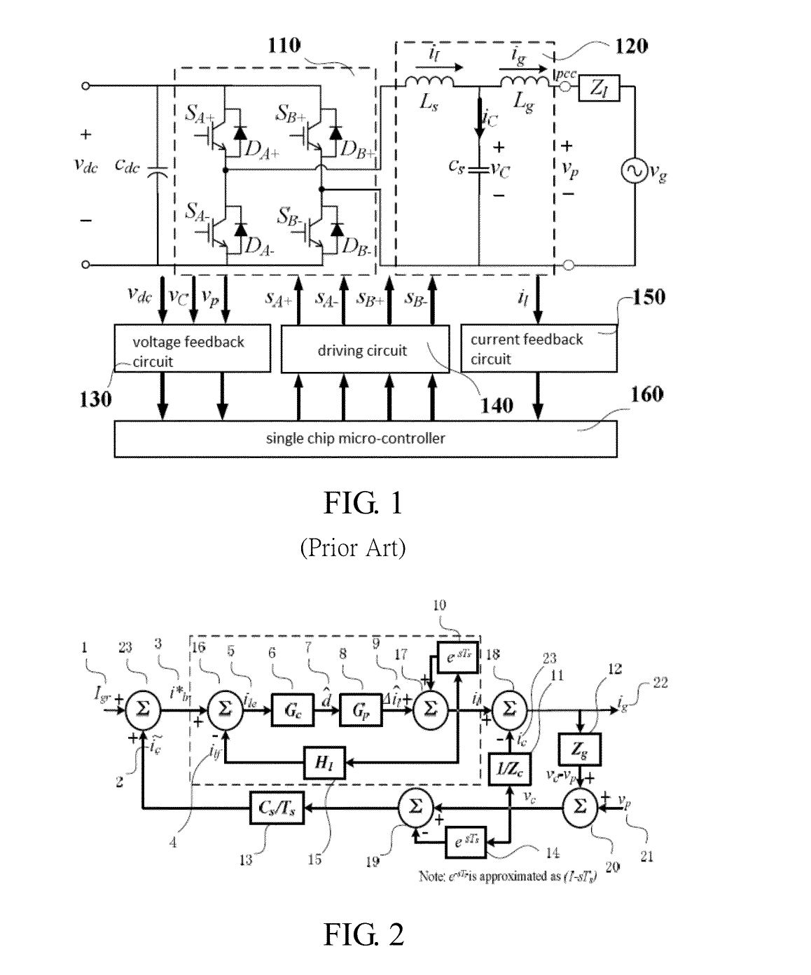

Firstly, refer to FIG. 1 for a circuit and control block diagram for a single-phase double-wire bi-directional inverter system according to a first embodiment of the present invention. The single-phase double-wire bi-directional inverter system itself belongs to the prior art. However, in the present embodiment, the inverter system is used together with the method and equations of the present invention, to modify inverter reference current to compensate for the distorted capacitor current caused by distorted voltage, in achieving suppressing merged grid current harmonics and generating ideal current of sine waves.

As shown in FIG. 1, the single-phase double-wire bi-directional inverter system 100 includes: a single-phase double-wire bi-directional inverter 110; an LCL filter 120, a voltage feedback circuit 130, a driving circuit 140, a current feedback circuit 150, and a single chip micro-controller 160. Wherein, the single-phase double-wire bi-directional inverter system 100 includes four switches, comprising respectively: a first switch (transistor SA+, diode DA+), a second switch (transistor SA−, diode DA−), the third switch (transistor SB+, diode DB+), and a fourth switch (transistor SB−, diode DB−). In the descriptions above, the first switch is connected to the second switch, with their connection point connected to a positive input end of the LCL filter 120; and the third switch is connected to the fourth switch, with their connection point connected to a negative input end of the LCL filter 120. The LCL filter 120 includes: inductors Ls and Lg connected in series; and a capacitor Cs connected thereto in parallel, such that the current flowing through are il, ig, and iC respectively. The voltage across the capacitor Cs is V_{c}. The output voltage of the LCL filter 120 is vₚ, and it is connected to a load. Voltage at input side of the single-phase double-wire bi-directional inverter system 100 is vdc, with this input side connected to an input capacitor cdc in parallel. The load impedance of LCL filter 120 is Z1, while the power grid voltage is vg.

In addition, one end of voltage feedback circuit 130 is connected to the LCL filter 120 and the single-phase double-wire bi-directional inverter 110, to receive from them the feedback voltage vdc, v_{c}, and vₚ, and transmit the feedback voltage to a single chip micro-controller 160, connected to the other end of the voltage feedback circuit 130. Moreover, current feedback circuit 150 is connected to LCL filter 120, to receive from it the feedback current iₗ, and transmit the feedback current to a single chip micro-controller 160, connected to the other end of the current feedback circuit 150. Further, one end of driving circuit 140 is connected to the single chip micro-controller 160, to receive from it instructions, and transmit the control signals SA+, SA−, SB+, and SB− to single-phase double-wire bi-directional inverter 110, connected to the other end of the driving circuit 140.

In the descriptions above, in the circuit and control block diagram for a single-phase double-wire bi-directional inverter system, the current tracing instruction (I_{gr}) of the inverter current (iₗ) is of a sine wave function at basic frequency (refer to equation 1). Through using the division-and-summation control, the inverter may accurately follow the current tracing instructions (I_{gr}). However, when the power grid connected to the inverter does have marked voltage harmonics, the power grid current (i_{g}) will have serious distortions. When the grid voltage contains harmonics, the capacitor current (i_{c}) in the filter will also have harmonics. In order to merge the sine wave current of basic frequency into the power grid, the current tracing instruction (I_{gr}) of the inverter current (iₗ) must be updated to a new reference current (i*ₗᵣ), as shown in Equation 1. Wherein, I_{gr} is a current tracing instruction and it is also a power grid reference current, as shown in Equation 2, such that [symbol] is an estimated capacitor current, and it can be obtained through using Equation 3. Equation 4 is used to estimate the v_{c}(n+1) in Equation 3, wherein, v_{c}(n) is the sensed capacitor voltage, vₚ(n) is the sensed duty division point (PCC) voltage; I_{gr} and vₚ are of the same phase, and I_{M} is the amplitude of I_{gr}.

Then, refer to FIG. 2 for an S domain (frequency domain) control block diagram of an equivalent circuit of a single-phase double-wire bi-directional inverter system utilized in implementing the first embodiment of the present invention. In FIG. 2, it utilizes the results obtained through using the Division and Summation (D & Σ) Control Technique to proceed with discussions and explanations. As such, it is beneficial to explain and discuss briefly the Division and Summation Control Technique. In general, in a digital control system, for an inductor, only one total current variation can be obtained in each switching cycle. Through using the Division and Summation Control Technique, a single switching cycle can be divided into a plurality of time intervals, with each time interval corresponding to a part of total current variation of an inductor. Then, use the Division and Summation Control Technique to sum up all the current variations of such an inductor in a switching cycle, so as to derive the control principle, as such making the measurement more precise and accurate.

As shown in FIG. 2, the functions and operation principles contained therein can be explained more clearly through the parameter values and/or element names of the respective numerals as follows:

1. merged power grid reference current; 2. estimated capacitor current required to be compensated; 3. inductor reference current traced by the inverter; 4. real feedback value of inductor current; 5. deviation between inductor current needs to be traced and the real value; 6. compensation gain of the controller; 7. variations of duty cycle ratio; 8. amplification gain of the circuit; 9. variations of inductor current of a circuit; 10,14 delayed a switching cycle T_{S} in digital control, namely, the value of previous cycle can be used in the present cycle; 11. impedance Z_{c}=1/sCₛ in filter capacitance frequency domain; 12. impedance Z_{g}=sL_{g} at the power grid side inductor frequency domain; 13

$$\frac{{C}_{S}}{{T}_{S}}$$

in

$${i}_{C} = {C}_{S} \frac{d {v}_{C}}{d t}$$

as realized in digital control; 15. inductor current feedback ratio, usually is 1; 16,17,18,19,20,23. adder; 21. duty division point voltage; 22. real merged power grid current.

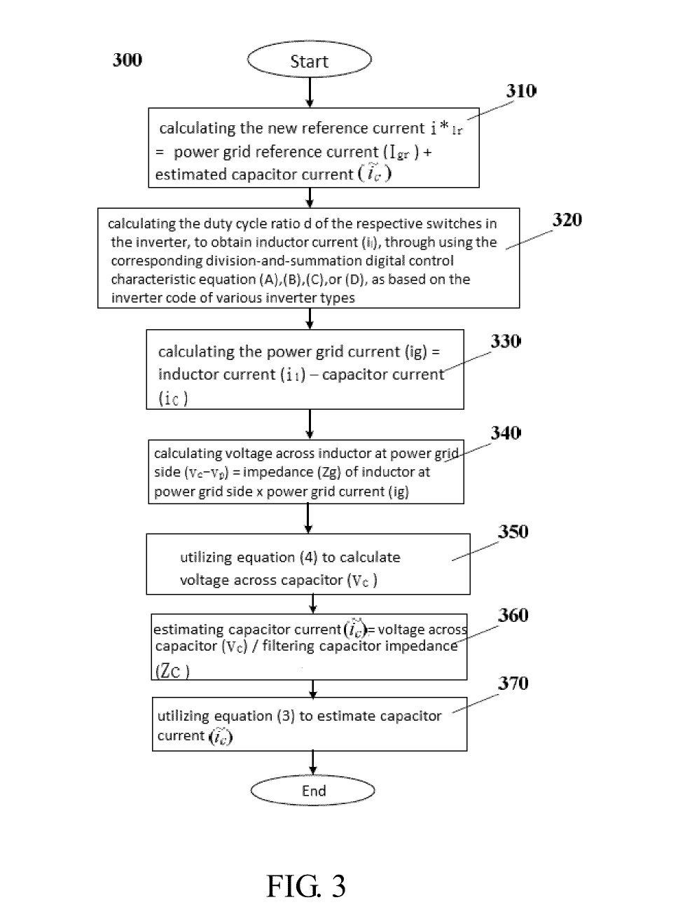

Subsequently, refer to FIG. 3 for a flowchart of the steps of an LCL capacitor current compensation and control method based on division and summation technique according to a first embodiment of the present invention. The flowchart of FIG. 3 corresponds to the control block diagram of FIG. 2. As shown in FIG. 3, the LCL capacitor current compensation and control method based on division and summation technique includes the following steps: calculating the new reference current i*ₗᵣ=power grid reference current (I_{gr})+estimated capacitor current ( [symbol] ) (step 310); calculating the duty cycle ratio d of the respective switches in the inverter, to obtain inductor current (iₗ), through using the corresponding division-and-summation digital control characteristic equation (A), (B), (C), or (D), as based on the inverter code of various inverter types (step 320); calculating the power grid current (i_{g})=inductor current (iₗ)−capacitor current (i_{c}) (step 330); calculating voltage across inductor at power grid side (v_{c}−vₚ)=impedance (Z_{g}) of inductor at power grid side x power grid current (i_{g}) (step 340); utilizing equation (4) to calculate voltage across capacitor (v_{c}) (step 350); estimating capacitor current ( [symbol] )=voltage across capacitor (v_{c})/filtering capacitor impedance (Z_{c}) (step 360); and utilizing equation (3) to estimate capacitor current ( [symbol] ) (step 370).

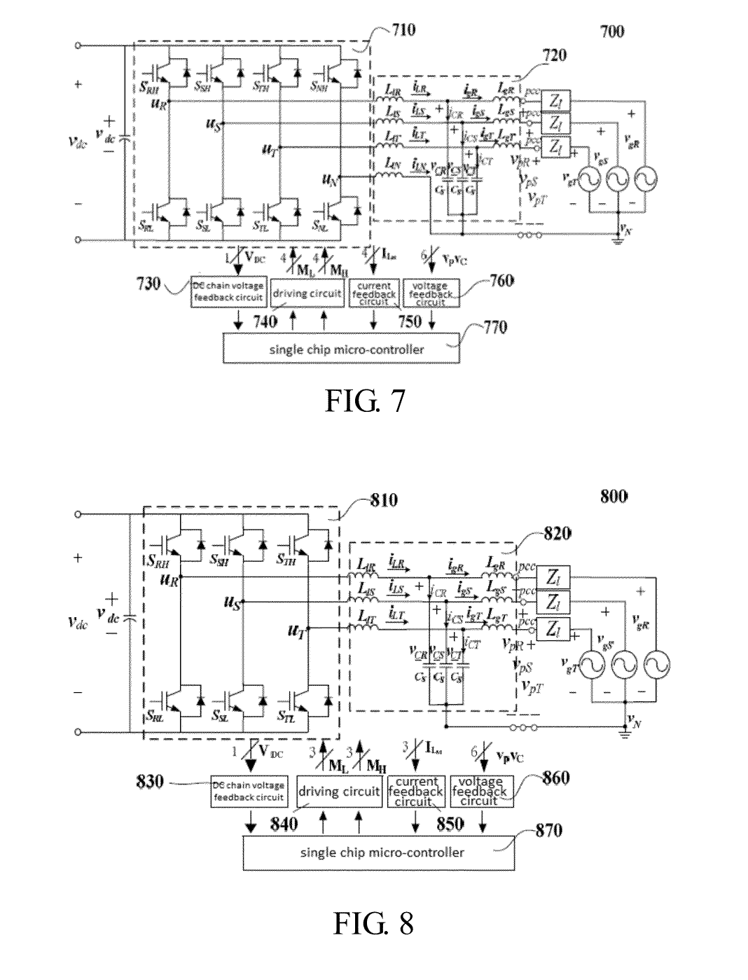

In the present invention, the types of inverter utilized in implementing the LCL capacitor current compensation and control method based on division and summation technique of the present invention may include the following: single-phase double-wire bi-directional inverter (FIG. 1), with its inverter code set as A01; three-phase four-wire bi-directional inverter (FIG. 7), with its inverter code set as A02;

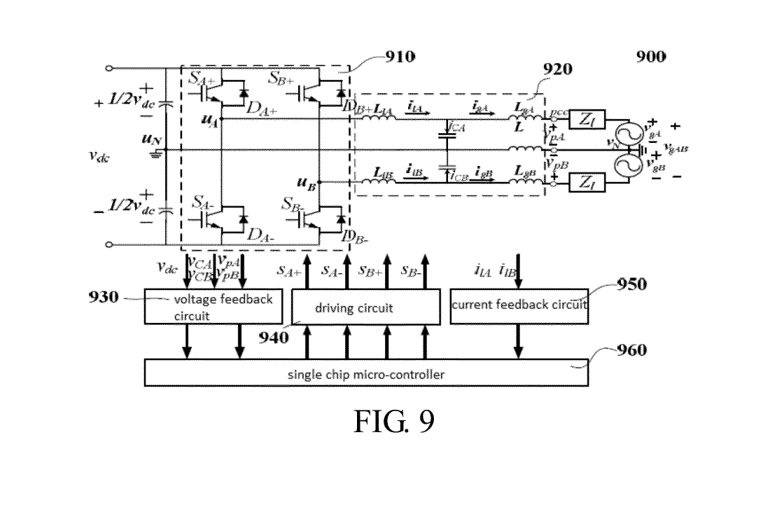

three-phase three-wire bi-directional inverter (FIG. 8), with its inverter code set as A03; and single-phase three-wire bi-directional inverter (FIG. 9), with its inverter code set as A04.

In step 320 mentioned above, in case the inverter code is A01, then execute the division-and-summation digital control characteristic equation (A); in case the inverter code is A02, then execute the division-and-summation digital control characteristic equation (B); in case the inverter code is A03, then execute the division-and-summation digital control characteristic equation (C); and in case the inverter code is A04, then execute the division-and-summation digital control characteristic equation (D).

It is worth to note that, in implementing the LCL capacitor current compensation and control method, since in the present embodiment, a single-phase double-wire bi-directional inverter is used, with its inverter code as A01. Therefore, it utilizes the corresponding division-and-summation digital control characteristic equation (A) to calculate inductor current (iₗ) and estimate capacitor current ( [symbol] ), and then make compensation (iₗ− [symbol] ) for the output current of the inverter, as such suppressing or eliminating harmonics, and producing grid current (i_{g}) of ideal sine wave.

In the descriptions above, FIG. 2 is an S domain (frequency domain) control block diagram, while FIG. 3 is the process flowchart corresponding to FIG. 2. In the conventional method, the inverter is viewed and treated as a voltage source. In contrast, in the present invention, the inverter is controlled as a current source (iₗ), and it is used to estimate capacitor current ( [symbol] ), to proceed with the compensation required. The compensated current (iₗ− [symbol] ) is filtered by the inductor Lg, to produce grid current (i_{g}). As shown in FIG. 2, wherein Gₚ can be obtained through using equation 5, G_{c} is a reciprocal of Gₚ. The purpose of this design is to eliminate the effect of variations of inductor Ls, chained DC voltage vdc, and switching cycle Ts, to increase the robustness of the system tracing the power grid current. The rest of the perimeters are explained as follows: H₁=1, Z_{g}=sL_{g}, Z_{C}=1/sCₛ, and e^{-sT}^{ₛ} can be approximated as (1−sTₛ) through using Taylor progression.

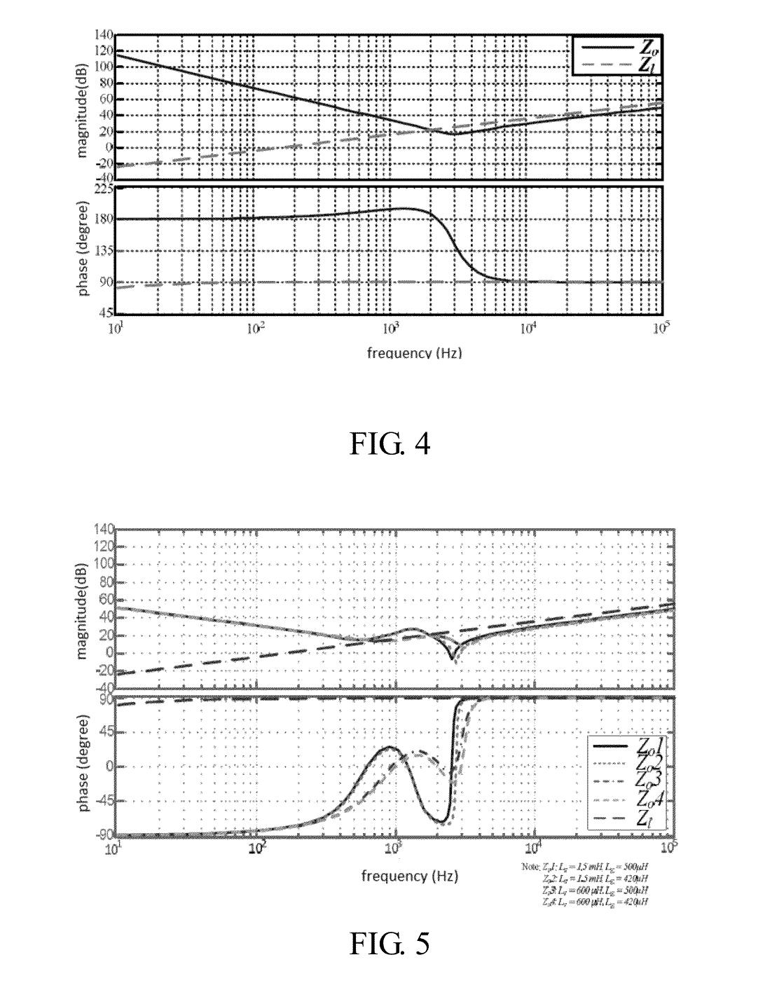

Then, refer to FIGS. 4 and 5. FIG. 4 is a plot of output impedance (Z₀) vs power grid impedance (Z₁) for an LCL capacitor current compensation and control method based on division and summation technique according to a first embodiment of the present invention. While FIG. 5 is a plot of output impedance (Z₀) vs power grid impedance (Z₁) taking into consideration of variations of inductors Ls and Lg, as based on the SPWM modulation approach of the prior art. Comparing FIG. 4 with FIG. 5, it is evident that, in FIG. 4, for the method of the present invention, the entire frequency section has higher phase angle tolerance, as such even the grid impedance (Z₁) is increased, the system is still be able to maintain stable operation. In contrast, in FIG. 5, for the method of the prior art, when the grid impedance (Z₁) is increased to a certain value, the phase angle tolerance of the system will degenerate. At this time, in case additional control is not applied to raise the phase angle tolerance, then the system will oscillate and dissipate. In addition, the present invention eliminate the influence of inductor (Ls) variation, therefore, the plot of the output impedance (Z₀) has only one curve. In contrast, the conventional method will be affected by the variations of inductor (Ls), so that the plot of the output impedance (Z₀) may have different curves. Further, at low frequency, the method of the present invention may provide higher impedance than the conventional method of the prior art, thus being able to serve as better equivalent current source.

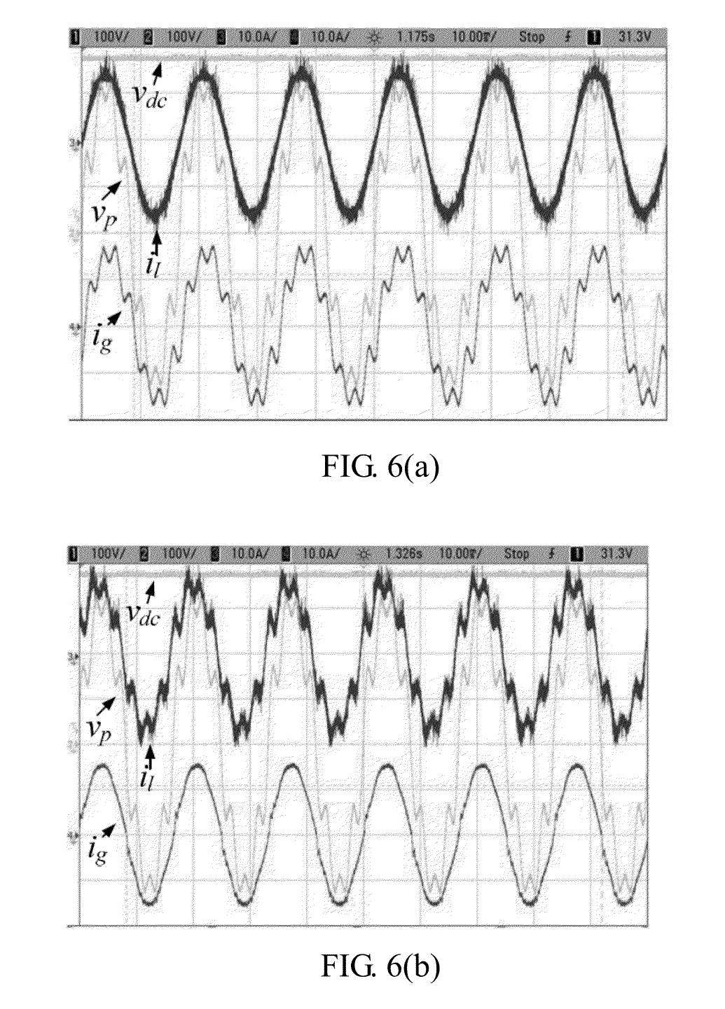

Refer to FIGS. 6(a) and 6(b) for real test curves for local power grid merged mode, when the grid voltage harmonics are present (as shown in Table 1). As shown in FIG. 6(a), in the prior art, when the capacitor current compensation and control is not utilized, the grid current (i_{g}) will be affected by grid voltage harmonics and be seriously distorted, with its waveform having saw-tooth shape, and having total harmonics distortion of 18.8%. In contrast, as shown in FIG. 6(b), when the capacitor current compensation and control is adopted, the grid current (i_{g}) is close to the ideal sine waves, with its total harmonics distortion reduced to 3.2%. From the figures mentioned above, it can be known that, the present invention indeed can reduce effectively the current harmonics distortion caused by grid voltage harmonics, to suppress or eliminate harmonics of power grid current, as such avoiding shortcomings and drawbacks of the prior art. The shortcomings are that, for the various electronic devices receiving and using the grid current having harmonics, its sensitivity and accuracy will be affected by the harmonics and degrade. Through using the LCL capacitor current compensation and control method based on division and summation technique of the present invention, the shortcomings of the prior art can be avoided.

Further, in table 1, PF means Power Factor; V_{THD} means voltage Total Harmonic Distortion; and I_{THD} means Current Total Harmonic Distortion.

In the following, refer to FIGS. 7, 8, and 9 respectively for a circuit and control block diagram for a three-phase four-wire bi-directional inverter system according to a second embodiment of the present invention, a three-phase three-wire bi-directional inverter system according to a third embodiment of the present invention, and single-phase three-wire bi-directional inverter system according to a fourth embodiment of the present invention. As shown in FIGS. 7, 8, and 9, the three kinds of inverter systems can also be applied the method used for the single-phase double-wire bi-directional inverter system of FIG. 1, for implementing the LCL capacitor current compensation and control, and to effectively reduce the total current harmonic distortion caused by grid voltage harmonic, hereby suppressing or eliminating the merged grid current harmonics, and avoiding the shortcomings of the prior art.

### Second Embodiment

### Three-Phase Four-Wire Bi-Directional Inverter System

Refer to FIG. 7 for a circuit and control block diagram for a three-phase four-wire bi-directional inverter system according to a second embodiment of the present invention. The three-phase four-wire bi-directional inverter system itself belongs to the prior art. However, in the present embodiment, the inverter system is used together with the method and equations of the present invention, to modify inverter reference current to compensate for the distorted capacitor current caused by distorted voltage, in achieving suppressing merged grid current harmonics and generating ideal current of sine waves.

As shown in FIG. 7, the three-phase four-wire bi-directional inverter system 700 includes: a three-phase four-wire bi-directional inverter 710; an LCL filter 720, a direct current chain voltage feedback circuit 730, a driving circuit 740, a current feedback circuit 750, a voltage feedback circuit 760, and a single chip micro-controller 770.

The structure and configuration of the present embodiment are similar to that of the single-phase double-wire bi-directional inverter system 100 of the first embodiment as shown in FIG. 1. The difference is that, the present embodiment utilizes 8 switches (each formed by a transistor and a diode), and a LCL filter formed by four sets of inductor-capacitor-inductors. In addition, in the present embodiment, the output of LCL filter is connected to three loads in the power grid, to generate 3 grid voltages. In the descriptions above, the 8 switches are sequentially as S_{RH}, S_{RL}, S_{SH}, S_{SL}, S_{TH}, S_{TL}, S_{NH}, S_{NL}. The four sets of inductor-capacitor-inductors (LCL) are sequentially as (L_{IR.}Cs, L_{gR}), (L_{IS}.Cs, L_{gS}), (L_{IT}.Cs, L_{gT}), (L_{IN}). The three loads are all Z₁, and the grid voltage are sequentially as V_{gR}, V_{gS}, and V_{gT}.

Wherein, the first switch is connected to the second switch, with their connection point connected to the first set inductor-capacitor-inductor (LCL) at the positive end of LCL filter. the third switch is connected to the fourth switch, with their connection point connected to the second set (LCL) at the positive end of LCL filter. The fifth switch is connected to the sixth switch, with their connection point connected to the third set inductor-capacitor-inductor (LCL) at the positive end of LCL filter. The seventh switch is connected to the eighth switch, with their connection point connected to the fourth set inductor-capacitor-inductor (LCL) at the positive end of LCL filter.

In addition, the direct current chain voltage feedback circuit 730 is connected between the three-phase four-wire bi-directional inverter 710 and the single chip micro-controller 770, for receiving feedback voltage V_{DC}, and transmitting it to the single chip micro-controller 770. The driving circuit 740 is connected between the three-phase four-wire bi-directional inverter 710 and the single chip micro-controller 770, for transmitting the driving signals M₁ and M_{R} to the three-phase four-wire bi-directional inverter 710. The current feedback circuit 750 is connected between the three-phase four-wire bi-directional inverter 710 and the single chip micro-controller 770, for receiving feedback current I_{LM}. The voltage feedback circuit 760 is connected between the LCL filter 720 and the single chip micro-controller 770, for receiving feedback voltage vₚ and v_{c}.

The operation principle of the three-phase four-wire bi-directional inverter 710 and LCL filter 720 of the present embodiment is similar to that of the single-phase double-wire bi-directional inverter system 100 and the LCL filter 120 of the first embodiment, people familiar with this field can infer to know it easily, so it will not be repeated here for brevity. Yet, it worth to note that, in the present embodiment, in performing the LCL capacitor current compensation and control method of the present invention, namely, in performing the method of FIG. 3, since its inverter code is A02, so it must utilize division-and-summation digital control characteristic equation (B), to calculate inductor current (iₗ) and obtain capacitor current ( [symbol] ), and then make compensation (iₗ− [symbol] ) for the output current of the inverter, as such suppressing or eliminating harmonics, and producing grid current (ig) of ideal sine wave.

Furthermore, the FIGS. 4, 5, 6(a), and 6(b) of the first embodiment can also be applied to the present embodiment.

### Third Embodiment

### Three-Phase Three-Wire Bi-Directional Inverter System

Refer to FIG. 8 for a circuit and control block diagram for a three-phase three-wire bi-directional inverter system according to a third embodiment of the present invention. The three-phase three-wire bi-directional inverter system itself belongs to the prior art. However, in the present embodiment, the inverter system is used together with the method and equations of the present invention, to modify inverter reference current to compensate for the distorted capacitor current caused by distorted voltage, in achieving suppressing merged grid current harmonics and generating ideal current of sine waves.

As shown in FIG. 8, the three-phase three-wire bi-directional inverter system 800 includes: a three-phase three-wire bi-directional inverter 810; an LCL filter 820, a direct current chain voltage feedback circuit 830, a driving circuit 840, a current feedback circuit 850, a voltage feedback circuit 860, and a single chip micro-controller 870.

The structure and configuration of the present embodiment are similar to that of the single-phase double-wire bi-directional inverter system 100 of the first embodiment as shown in FIG. 1. The difference is that, the present embodiment utilizes 6 switches (each formed by a transistor and a diode), and a LCL filter formed by three sets of inductor-capacitor-inductors. In addition, in the present embodiment, the output of LCL filter is connected to three loads in the power grid, to produce 3 grid voltages. In the descriptions above, the 6 switches are sequentially as S_{RH}, S_{RL}, S_{SH}, S_{SL}, S_{TH}, S_{TL}; while the three sets of inductor-capacitor-inductors (LCL) are sequentially as (L_{IR.}Cs, L_{gR}), (L_{IS}.Cs, L_{gS}), (L_{IT}.Cs, L_{gT}). The three loads are all Z₁, and the grid voltage are sequentially as V_{gR}, V_{gS}, and V_{gT}.

Wherein, the first switch is connected to the second switch, with their connection point connected to the first set inductor-capacitor-inductors (LCL) at the positive end of LCL filter. the third switch is connected to the fourth switch, with their connection point connected to the second set (LCL) at the positive end of LCL filter. The fifth switch is connected to the sixth switch, with their connection point connected to the third set inductor-capacitor-inductors (LCL) at the positive end of LCL filter.

In addition, the direct current chain voltage feedback circuit 830 is connected between the three-phase three-wire bi-directional inverter 810 and the single chip micro-controller 870, for receiving feedback voltage V_{DC}, and transmitting it to the single chip micro-controller 870. The driving circuit 840 is connected between the three-phase three-wire bi-directional inverter 810 and the single chip micro-controller 870, for transmitting the driving signals M₁ and M_{R} to the three-phase three-wire bi-directional inverter 810. The current feedback circuit 850 is connected between the three-phase three-wire bi-directional inverter 810 and the single chip micro-controller 870, for receiving feedback current I_{LM}, and transmitting it to the single chip micro-controller 870. The voltage feedback circuit 860 is connected between the LCL filter 820 and the single chip micro-controller 870, for receiving feedback voltage vₚ, and v_{c}.

The operation principle of the three-phase three-wire bi-directional inverter 810 and LCL filter 820 of the present embodiment is similar to that of the single-phase double-wire bi-directional inverter system 100 and the LCL filter 120 of the first embodiment, people familiar with this field can infer to know it easily, so it will not be repeated here for brevity. Yet, it worth to note that, in the present embodiment, in performing the LCL capacitor current compensation and control method of the present invention, namely, in performing the method of FIG. 3, since its inverter code is A03, so it must utilize division-and-summation digital control characteristic equation (C), to calculate the inductor current (iₗ) to obtain the capacitor current ( [symbol] ), and then make compensation (iₗ− [symbol] ) for the output current of the inverter, as such suppressing or eliminating harmonics, and producing grid current (ig) of ideal sine wave.

Furthermore, the FIGS. 4, 5, 6(a), and 6(b) of the first embodiment can also be applied to the present embodiment.

### Fourth Embodiment

### Single-Phase Three-Wire Bi-Directional Inverter System

Refer to FIG. 9 for a circuit and control block diagram for a single-phase three-wire bi-directional inverter system according to a fourth embodiment of the present invention. The single-phase three-wire bi-directional inverter system itself belongs to the prior art. However, in the present embodiment, the inverter system is used together with the method and equations of the present invention, to modify the inverter reference current to compensate for the distorted capacitor current caused by distorted voltage, in achieving suppressing the merged grid current harmonics and producing ideal current of sine waves.

As shown in FIG. 9, the single-phase three-wire bi-directional inverter system 900 includes: a single-phase three-wire bi-directional inverter 910; an LCL filter 920, a voltage feedback circuit 930, a driving circuit 940, a current feedback circuit 950, and a single chip micro-controller 960.

The structure and configuration of the present embodiment are similar to that of the single-phase double-wire bi-directional inverter system 100 of the first embodiment as shown in FIG. 1. The difference is that, in the present embodiment, the single-phase three-wire bi-directional inverter 910 utilizes 4 switches (each formed by a transistor and a diode), and a LCL filter 920 formed by two sets of inductor-capacitor-inductors (LCL). In addition, in the present embodiment, the output of LCL filter is connected to two loads in the power grid, to produce 2 grid voltages. In the descriptions above, the 4 switches are respectively: a first switch (transistor SA+, diode DA+), a second switch (transistor SA−, diode DA−), a third switch (transistor SB+, diode DB+), and a fourth switch (transistor SB−, diode DB−). While the two sets of inductor-capacitor-inductors (LCL) are sequentially as (L_{1A}.CA, L_{gA}), (L_{1B}.CB, L_{gB}). The two loads are both Z₁, and the grid voltage are V_{gA} and V_{gB}.

Wherein, the first switch is connected to the second switch, with their connection point connected to the first set of inductor-capacitor-inductors (LCL) at the positive end of LCL filter. the third switch is connected to the fourth switch, with their connection point connected to the second set (LCL) at the positive end of LCL filter.

In addition, one end of the voltage feedback circuit 930 is connected to the single-phase three-wire bi-directional inverter 910 and the LCL filter 920, to receive from them the feedback voltage Vdc, V_{CA}, V_{CB}, vpA, vpB, and transmit the voltages to the single chip micro-controller 960 connected to its other end. Further, current feedback circuit 950 is connected to the LCL filter 920, to receive from it the feed back current i_{1A} and i_{1B}, and transmit them to the single chip micro-controller 960. Moreover, one end of the driving circuit 940 is connected to the single chip micro- controller 960, to receive from it instructions, and then transmit the control signals SA+, SA−, SB+, and SB− to the single-phase three-wire bi-directional inverter 910 connected to the other end of the driving circuit 940.

The operation principle of the single-phase three-wire bi-directional inverter 910 and LCL filter 920 of the present embodiment is similar to that of the single-phase double-wire bi-directional inverter system 100 and the LCL filter 120 of the first embodiment, people familiar with this field can infer to know it easily, so it will not be repeated here for brevity. Yet, it worth to note that, in the present embodiment, in performing the LCL capacitor current compensation and control method of the present invention, namely, in performing the method of FIG. 3, since its inverter code is A04, so it must utilize division-and-summation digital control characteristic equation (D), to calculate inductor current (iₗ), to estimate capacitor current ( [symbol] ), and then make compensation (iₗ− [symbol] ) for the output current of the inverter, as such suppressing or eliminating harmonics, and producing grid current (ig) of ideal sine wave.

Furthermore, the FIGS. 4, 5, 6(a), and 6(b) of the first embodiment can also be applied to the present embodiment.

In the first embodiment to the fourth embodiment mentioned above, the essence of design of the micro-controller is to integrate a central processing unit (CPU), a random access memory (RAM), a read only memory (ROM), an input/output device (I/O), and an analog-to-digital converter (A/D) on a single chip, such that it has the function of a micro computer. In the embodiments mentioned above, the steps and equations utilized in the LCL capacitor current compensation and control method based on division and summation technique, can be stored in the memory of the single chip micro-controller as shown in FIGS. 1, 7, 8, 9 in a form of software or computer program. When it is required to be executed, it is loaded into the main memory to be performed by CPU, in achieving the objective of eliminating current harmonics in a power grid.

Summing up the above, the present invention provides an LCL capacitor current compensation and control method based on division and summation technique, to overcome the shortcomings and drawbacks of the prior art. The compensation and control method takes into considerations of inductance variations, and it views an inverter as a current source. As such, through modifying reference current of inverter to compensate for the distorted capacitor current caused by a distorted voltage, it is able to suppress harmonics in current of a merged power grid, so as to achieve ideal sine wave. The method of the present invention is capable of avoiding the deficiency of the prior art that, degradation of the sensitivity and accuracy of the electronic device receiving and using this type of merged grid current as caused by the harmonics contained therein. Further, the method of the present invention is able to achieve the objective of accurately tracing power grid current, attaining high voltage harmonic suppression ratio, and realizing high stability tolerance. Therefore, the present invention is able to attain the effect not anticipated in the prior art, thus fulfill patent requirements and has patent value.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

TABLE 1

| | | | | without adding | with added |
|---|---|---|---|---|---|
| | | | | capacitor | capacitor |
| | | | | current compen- | current compen- |
| | number | | | sation control | sation control |
| | of har- | | test | (local power grid | (local power grid |
| case | monics | % | item | merged mode) | merged mode) |
| 1 | 5 | 9.8 | PF | 0.96 | 0.98 |
| 2 | 7 | 15.8 | V_{THD}(%) | 18.5 | 18.4 |
| 3 | 8 | 2.16 | I_{THD}(%) | 18.8 | 3.2 |

$$\begin{matrix}{i}_{lr}^{*} = {I}_{gr} + & equation 1 \\ {I}_{gr} = {I}_{M} sin ( ω {T}_{s} ) & equation 2 \\ = \frac{{C}_{s} ( {v}_{c} ( n + 1 ) - {v}_{c} ( n ) )}{{T}_{s}} & equation 3 \\ {\tilde{v}}_{c} ( n + 1 ) = {v}_{p} ( n ) + \frac{{L}_{g} ( {I}_{gr} ( n + 1 ) - {I}_{gr} ( n - 1 ) )}{{T}_{s}} & equation 4 \\ {G}_{p} = \frac{\partial Δ {i}_{l}}{\partial d} = \frac{Δ {\hat{ i}}_{l}}{\hat{d}} = \frac{2 {v}_{dc} {T}_{S}}{{L}_{S}} & equation 5 \\ {G}_{c} = \frac{1}{{G}_{p}} = \frac{{L}_{S}}{2 {v}_{dc} {T}_{S}} & equation 6\end{matrix}$$

division-and-summation digital control characteristic equation (A):

$$d = \frac{1}{2} + \frac{{v}_{c}}{2 {v}_{d c}} + \frac{Δ {i}_{l} \cdot {L}_{s ( {i}_{l} )}}{2 {v}_{d c} \cdot {T}_{s}} .$$

division-and-summation digital control characteristic equation (B):
interval 0°˜60°:

$$[ \begin{matrix}{d}_{RH} \\ {d}_{SL} \\ {d}_{TH} \\ {d}_{NH}\end{matrix} ] = [ \begin{matrix}\frac{{L}_{R ( {i}_{R} )} Δ {i}_{R} - {L}_{S ( {i}_{S} )} Δ {i}_{S}}{{v}_{D C} \cdot {T}_{S}} \\ 0 \\ \frac{- {L}_{S ( {i}_{S} )} Δ {i}_{S} + {L}_{T ( {i}_{T} )} Δ {i}_{T}}{{v}_{D C} \cdot {T}_{S}} \\ \frac{- {L}_{N ( {i}_{N} )} Δ {i}_{R} - ( {L}_{S ( {i}_{S} )} + {L}_{N ( {i}_{N} )} ) Δ {i}_{S} - {L}_{N ( {i}_{N} )} Δ {i}_{T}}{{v}_{D C} \cdot {T}_{S}}\end{matrix} ] + [ \begin{matrix}\frac{{v}_{RS}}{{v}_{D C}} \\ 1 \\ \frac{- {v}_{ST}}{{v}_{D C}} \\ \frac{- {v}_{SN}}{{v}_{D C}}\end{matrix} ] ,$$

interval 60°˜120°:

$$[ \begin{matrix}{d}_{RH} \\ {d}_{SL} \\ {d}_{TL} \\ {d}_{NL}\end{matrix} ] = [ \begin{matrix}0 \\ \frac{{L}_{R ( {i}_{R} )} Δ {i}_{R} - {L}_{S ( {i}_{S} )} Δ {i}_{S}}{{v}_{D C} \cdot {T}_{S}} \\ \frac{{L}_{R ( {i}_{R} )} Δ {i}_{R} - {L}_{T ( {i}_{T} )} Δ {i}_{T}}{{v}_{D C} \cdot {T}_{S}} \\ \frac{( {L}_{R ( {i}_{R} )} + {L}_{N ( {i}_{N} )} ) Δ {i}_{R} + {L}_{N ( {i}_{N} )} Δ {i}_{S} + {L}_{N ( {i}_{N} )} Δ {i}_{T}}{{v}_{D C} \cdot {T}_{S}}\end{matrix} ] + [ \begin{matrix}1 \\ \frac{{v}_{RS}}{{v}_{D C}} \\ \frac{- {v}_{TR}}{{v}_{D C}} \\ \frac{{v}_{RN}}{{v}_{D C}}\end{matrix} ] ,$$

interval 120°˜180°:

$$[ \begin{matrix}{d}_{RH} \\ {d}_{SH} \\ {d}_{TL} \\ {d}_{NH}\end{matrix} ] = [ \begin{matrix}\frac{{L}_{R ( {i}_{R} )} Δ {i}_{R} - {L}_{T ( {i}_{T} )} Δ {i}_{T}}{{v}_{D C} \cdot {T}_{S}} \\ \frac{{L}_{S ( {i}_{S} )} Δ {i}_{S} - {L}_{T ( {i}_{T} )} Δ {i}_{T}}{{v}_{D C} \cdot {T}_{S}} \\ 0 \\ \frac{- {L}_{N ( {i}_{N} )} Δ {i}_{R} - {L}_{N ( {i}_{N} )} Δ {i}_{S} - ( {L}_{T ( {i}_{T} )} + {L}_{N ( {i}_{N} )} ) Δ {i}_{T}}{{v}_{D C} \cdot {T}_{S}}\end{matrix} ] + [ \begin{matrix}\frac{- {v}_{TR}}{{v}_{D C}} \\ \frac{{v}_{ST}}{{v}_{D C}} \\ 1 \\ \frac{- {v}_{TN}}{{v}_{D C}}\end{matrix} ] ,$$

interval 180°˜240°:

$$[ \begin{matrix}{d}_{RL} \\ {d}_{SH} \\ {d}_{TL} \\ {d}_{NL}\end{matrix} ] = [ \begin{matrix}\frac{- {L}_{R ( {i}_{R} )} Δ {i}_{R} + {L}_{S ( {i}_{S} )} Δ {i}_{S}}{{v}_{D C} \cdot {T}_{S}} \\ 0 \\ \frac{{L}_{S ( {i}_{S} )} Δ {i}_{S} - {L}_{T ( {i}_{T} )} Δ {i}_{T}}{{v}_{D C} \cdot {T}_{S}} \\ \frac{{L}_{N ( {i}_{N} )} Δ {i}_{R} - ( {L}_{S ( {i}_{S} )} + {L}_{N ( {i}_{N} )} ) Δ {i}_{S} + {L}_{N ( {i}_{N} )} Δ {i}_{T}}{{v}_{D C} \cdot {T}_{S}}\end{matrix} ] + [ \begin{matrix}\frac{- {v}_{RS}}{{v}_{D C}} \\ 1 \\ \frac{{v}_{ST}}{{v}_{D C}} \\ \frac{{v}_{SN}}{{v}_{D C}}\end{matrix} ] ,$$

interval 240°˜300°:

$$[ \begin{matrix}{d}_{RL} \\ {d}_{SH} \\ {d}_{TH} \\ {d}_{NH}\end{matrix} ] = [ \begin{matrix}0 \\ \frac{- {L}_{R ( {i}_{R} )} Δ {i}_{R} + {L}_{S ( {i}_{S} )} Δ {i}_{S}}{{v}_{D C} \cdot {T}_{S}} \\ \frac{- {L}_{R ( {i}_{R} )} Δ {i}_{R} + {L}_{T ( {i}_{T} )} Δ {i}_{T}}{{v}_{D C} \cdot {T}_{S}} \\ \frac{- ( {L}_{R ( {i}_{R} )} + {L}_{N ( {i}_{N} )} ) Δ {i}_{R} + {L}_{N ( {i}_{N} )} Δ {i}_{S} + {L}_{N ( {i}_{N} )} Δ {i}_{T}}{{v}_{D C} \cdot {T}_{S}}\end{matrix} ] + [ \begin{matrix}1 \\ \frac{- {v}_{RS}}{{v}_{D C}} \\ \frac{{v}_{TR}}{{v}_{D C}} \\ \frac{- {v}_{RN}}{{v}_{D C}}\end{matrix} ] ,$$

interval 300°˜360°:

$$[ \begin{matrix}{d}_{RL} \\ {d}_{SL} \\ {d}_{TH} \\ {d}_{NL}\end{matrix} ] = [ \begin{matrix}\frac{- {L}_{R ( {i}_{R} )} Δ {i}_{R} + {L}_{T ( {i}_{T} )} Δ {i}_{T}}{{v}_{D C} \cdot {T}_{S}} \\ \frac{- {L}_{S ( {i}_{S} )} Δ {i}_{S} + {L}_{T ( {i}_{T} )} Δ {i}_{T}}{{v}_{D C} \cdot {T}_{S}} \\ 0 \\ \frac{{L}_{N ( {i}_{N} )} Δ {i}_{R} + {L}_{N ( {i}_{N} )} Δ {i}_{S} + ( {L}_{T ( {i}_{T} )} + {L}_{N ( {i}_{N} )} ) - Δ {i}_{T}}{{v}_{D C} \cdot {T}_{S}}\end{matrix} ] + [ \begin{matrix}\frac{{v}_{TR}}{{v}_{D C}} \\ \frac{- {v}_{ST}}{{v}_{D C}} \\ 1 \\ \frac{{v}_{TN}}{{v}_{D C}}\end{matrix} ] .$$

division-and-summation digital control characteristic equation (C):
interval 0°˜60°:

$$[ \begin{matrix}{d}_{RH} \\ {d}_{SL} \\ {d}_{TH}\end{matrix} ] = [ \begin{matrix}\frac{( {L}_{R ( {i}_{R} )} + {L}_{S ( {i}_{S} )} ) Δ {i}_{L ( R )} + {L}_{S ( {i}_{S} )} Δ {i}_{L ( T )}}{{v}_{D C} \cdot {T}_{S}} \\ 0 \\ \frac{( {L}_{T ( {i}_{T} )} + {L}_{S ( {i}_{S} )} ) Δ {i}_{L ( T )} + {L}_{S ( {i}_{S} )} Δ {i}_{L ( R )}}{{v}_{D C} \cdot {T}_{S}}\end{matrix} ] + [ \begin{matrix}\frac{{v}_{RS}}{{v}_{D C}} \\ 1 \\ - \frac{{v}_{ST}}{{v}_{D C}}\end{matrix} ] ,$$

interval 60°˜120°:

$$[ \begin{matrix}{d}_{RH} \\ {d}_{SL} \\ {d}_{TL}\end{matrix} ] = [ \begin{matrix}0 \\ \frac{( {L}_{S ( {i}_{S} )} + {L}_{R} ) Δ {i}_{L ( S )} + {L}_{R ( {i}_{R} )} Δ {i}_{L ( T )}}{{v}_{D C} \cdot {T}_{S}} \\ \frac{( {L}_{T ( {i}_{T} )} + {L}_{R ( {i}_{R} )} ) Δ {i}_{L ( T )} + {L}_{R ( {i}_{R} )} Δ {i}_{L ( S )}}{{v}_{D C} \cdot {T}_{S}}\end{matrix} ] + [ \begin{matrix}1 \\ \frac{{v}_{RS}}{{v}_{D C}} \\ - \frac{{v}_{TR}}{{v}_{D C}}\end{matrix} ] ,$$

interval 120°˜180°:

$$[ \begin{matrix}{d}_{RH} \\ {d}_{SH} \\ {d}_{TL}\end{matrix} ] = [ \begin{matrix}\frac{( {L}_{R ( {i}_{R} )} + {L}_{T ( {i}_{T} )} ) Δ {i}_{L ( R )} + {L}_{T ( {i}_{T} )} Δ {i}_{L ( S )}}{{v}_{D C} \cdot {T}_{S}} \\ \frac{( {L}_{S ( {i}_{S} )} + {L}_{T ( {i}_{T} )} ) Δ {i}_{L ( S )} + {L}_{T ( {i}_{T} )} Δ {i}_{L ( R )}}{{v}_{D C} \cdot {T}_{S}} \\ 0\end{matrix} ] + [ \begin{matrix}- \frac{{v}_{TR}}{{v}_{D C}} \\ \frac{{v}_{ST}}{{v}_{D C}} \\ 1\end{matrix} ] ,$$

interval 180°˜240°

$$[ \begin{matrix}{d}_{RL} \\ {d}_{SH} \\ {d}_{TL}\end{matrix} ] = [ \begin{matrix}\frac{( {L}_{R ( {i}_{R} )} + {L}_{S ( {i}_{S} )} ) Δ {i}_{L ( R )} + {L}_{S ( {i}_{S} )} Δ {i}_{L ( T )}}{{v}_{D C} \cdot {T}_{S}} \\ 0 \\ \frac{( {L}_{T ( {i}_{T} )} + {L}_{S ( {i}_{S} )} ) Δ {i}_{L ( T )} + {L}_{S ( {i}_{S} )} Δ {i}_{L ( R )}}{{v}_{D C} \cdot {T}_{S}}\end{matrix} ] + [ \begin{matrix}- \frac{{v}_{RS}}{{v}_{D C}} \\ 1 \\ \frac{{v}_{ST}}{{v}_{D C}}\end{matrix} ] ,$$

interval 240°˜300°

$$[ \begin{matrix}{d}_{RL} \\ {d}_{SH} \\ {d}_{TH}\end{matrix} ] = [ \begin{matrix}0 \\ \frac{( {L}_{S ( {i}_{S} )} + {L}_{R ( {i}_{R} )} ) Δ {i}_{L ( S )} + {L}_{R ( {i}_{R} )} Δ {i}_{L ( T )}}{{v}_{D C} \cdot {T}_{S}} \\ \frac{( {L}_{T ( {i}_{T} )} + {L}_{R ( {i}_{R} )} ) Δ {i}_{L ( T )} + {L}_{R ( {i}_{R} )} Δ {i}_{L ( S )}}{{v}_{D C} \cdot {T}_{S}}\end{matrix} ] + [ \begin{matrix}1 \\ \frac{{v}_{RS}}{{v}_{D C}} \\ - \frac{{v}_{TR}}{{v}_{D C}}\end{matrix} ] ,$$

interval 300°˜360°

$$[ \begin{matrix}{d}_{RL} \\ {d}_{SL} \\ {d}_{TH}\end{matrix} ] = [ \begin{matrix}\frac{( {L}_{R ( {i}_{R} )} + {L}_{T ( {i}_{T} )} ) Δ {i}_{L ( R )} + {L}_{T ( {i}_{T} )} Δ {i}_{L ( S )}}{{v}_{D C} \cdot {T}_{S}} \\ \frac{( {L}_{S ( {i}_{S} )} + {L}_{T ( {i}_{T} )} ) Δ {i}_{L ( S )} + {L}_{T ( {i}_{T} )} Δ {i}_{L ( R )}}{{v}_{D C} \cdot {T}_{S}} \\ 0\end{matrix} ] + [ \begin{matrix}\frac{{v}_{TR}}{{v}_{D C}} \\ - \frac{{v}_{ST}}{{v}_{D C}} \\ 1\end{matrix} ] .$$

division-and-summation digital control characteristic equation (D):

$$d = \frac{1}{2} + \frac{{v}_{c}}{2 {v}_{d c}} + \frac{Δ {i}_{l} \cdot {L}_{s ( {i}_{l} )}}{2 {v}_{d c} \cdot {T}_{s}} .$$

What is claimed is:

1. An LCL capacitor current compensation and control method based on division and summation technique, comprising following steps:
calculating a new reference current i*₁ᵣ=power grid reference current (I_{gr})+estimated capacitor current ( [symbol] );
calculating a duty cycle ratio d of respective switches in an inverter to obtain inductor current (i₁), through using a corresponding division-and-summation digital control characteristic equation (A), (B), (C), or (D), as based on an inverter code of various inverter types;
calculating a power grid current (ig)=inductor current (i₁)−capacitor current (i_{c});
calculating voltage across an inductor at a power grid side (v_{c}−vₚ)=impedance (Zg) of said inductor at power grid side x power grid current (ig);
utilizing equation (4) to calculate voltage across a capacitor (v_{c});
estimating capacitor current ( [symbol] )=voltage across said capacitor (v_{c})/filtering capacitor impedance (Zc); and
utilizing equation (3) to estimate a capacitor current ( [symbol] ).

2. The LCL capacitor current compensation and control method based on division and summation technique as claimed in claim 1, wherein said inverter includes following types: single-phase double-wire bi-directional inverter system, with its inverter code set at A01; three-phase four-wire bi-directional inverter system, with its inverter code set at A02; three-phase three-wire bi-directional inverter system, with its inverter code set at A03; and single-phase three-wire bi-directional inverter system, with its inverter code set at A04.

3. The LCL capacitor current compensation and control method based on division and summation technique as claimed in claim 2, wherein in case said inverter code is A01, then said single-phase double-wire bi-directional inverter system executes said division-and-summation digital control characteristic equation (A).

4. The LCL capacitor current compensation and control method based on division and summation technique as claimed in claim 2, wherein in case said inverter code is A02, then said three-phase four-wire bi-directional inverter system executes said division-and-summation digital control characteristic equation (B).

5. The LCL capacitor current compensation and control method based on division and summation technique as claimed in claim 2, wherein in case said inverter code is A03, then said three-phase three-wire bi-directional inverter system executes said division-and-summation digital control characteristic equation (C).

6. The LCL capacitor current compensation and control method based on division and summation technique as claimed in claim 2, wherein in case said inverter code is A04, then said single-phase three-wire bi-directional inverter system executes said division-and-summation digital control characteristic equation (D).

7. The LCL capacitor current compensation and control method based on division and summation technique as claimed in claim 1, wherein said equation 4 is
$$( n + 1 ) = {v}_{p} ( n ) + \frac{{L}_{g} ( {I}_{g r} ( n + 1 ) - {I}_{g r} ( n - 1 ) )}{{T}_{S}}$$

8. The LCL capacitor current compensation and control method based on division and summation technique as claimed in claim 1, wherein said equation 3 is
$$= \frac{{C}_{s} ( {v}_{c} ( n + 1 ) - {v}_{c} ( n ) )}{{T}_{S}}$$

9. The LCL capacitor current compensation and control method based on division and summation technique as claimed in claim 1, wherein said LCL capacitor current compensation and control method is used in said single-phase double-wire bi-directional inverter system, said three-phase four-wire bi-directional inverter system, said three-phase three-wire bi-directional inverter system, and said single-phase three-wire bi-directional inverter system, and through modifying reference current of an inverter to compensate for a capacitor current for a distorted voltage, to suppress harmonics in current of a merged power grid, so as to achieve ideal sine wave, to avoid deficiency of prior art that, degradation of the sensitivity and accuracy of an electronic device receiving and using this type of merged grid current as caused by the harmonics contained therein, as such achieving objective of accurately tracing power grid current, attaining high voltage harmonic suppression ratio, and realizing high stability tolerance.
